(19) United States
(12) Patent Application Publication
(10) Pub. No.: US 2025/0194162 A1
(43) Pub. Date: Jun. 12, 2025

(54) SOURCE/DRAIN REGIONS HAVING DIFFERENT SIDEWALL SHAPES

(71) Applicant: International Business Machines Corporation, Armonk, NY (US)

(72) Inventors: Sagarika Mukesh, Albany, NY (US); Ruilong Xie, Niskayuna, NY (US); Alexander Reznicek, Troy, NY (US); Tsung-Sheng Kang, Ballston Lake, NY (US)

(21) Appl. No.: 18/535,075

(22) Filed: Dec. 11, 2023

(51) Int. Cl. H01L 29/786; H01L 27/088; H01L 29/06; H01L 29/423; H01L 29/66; H01L 29/775

(52) U.S. Cl. CPC H10D 30/6757; H10D 30/43; H10D 30/6735; H10D 62/121; H10D 64/021; H10D 84/83

(57) ABSTRACT

A semiconductor structure includes a first source/drain region having a first sidewall shape and a second source/drain region having a second sidewall shape, the second sidewall shape being different than the first sidewall shape. At least one of the first source/drain region and the second source/drain region is disposed over a placeholder layer. The first source/drain region may be an n-type source/drain region and the second source/drain region may be a p-type source/drain region, and the first sidewall shape may be diamond-shaped sidewalls and the second sidewall shape may be trench-confined sidewalls.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

A field-effect transistor (FET) is a three-terminal device having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the area of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm node and beyond. A general process flow for formation of a nanosheet stack involves removing sacrificial layers, which may be formed of Silicon Germanium (SiGe), between sheets of channel material, which may be formed of Silicon (Si).

### SUMMARY

Embodiments of the invention provide techniques for forming semiconductor structures having source/drain regions with different sidewall shapes. For example, the semiconductor structure may include a nanosheet transistor structure, where n-type source/drain regions have diamond-shaped sidewalls and where p-type source/drain regions have trench-confined sidewalls.

In one embodiment, a semiconductor structure includes a first source/drain region having a first sidewall shape and a second source/drain region having a second sidewall shape, the second sidewall shape being different than the first sidewall shape. At least one of the first source/drain region and the second source/drain region is disposed over a placeholder layer.

The semiconductor structure advantageously has reduced susceptibility to etch-out of the source/drain regions during channel release processing for nanosheet channel layers in a nanosheet stack, where at least one of the first source/drain region and the second source/drain region is formed of a same material (e.g., silicon germanium (SiGe)) as sacrificial layers in the nanosheet stack.

In another exemplary embodiment, as may be combined with the preceding paragraphs, the first source/drain region may be an n-type source/drain region and the second source/drain region may be a p-type source/drain region. The first sidewall shape may comprise diamond-shaped sidewalls and the second sidewall shape may comprise trench-confined sidewalls. The second source/drain region and the placeholder layer may be formed of SiGe, where a first percentage of germanium (Ge) in the second source/drain region is greater than a second percentage of Ge in the placeholder layer.

In another exemplary embodiment, as may be combined with the preceding paragraphs, the first source/drain region may be disposed over the placeholder layer, and the semiconductor structure may further include a backside contact to the second source/drain region. The semiconductor structure may further include a dielectric liner disposed over shallow trench isolation regions surrounding a portion of sidewalls of the backside contact. The dielectric liner may be a first material different than a second material of gate spacers surrounding gate stacks of the semiconductor structure. The semiconductor structure may further include residual frontside contact material on a frontside of the second source/drain region. The semiconductor structure may further include a frontside contact on a frontside of the first source/drain region and a local interconnect extending horizontally from the frontside contact to at least a portion of an area of an interlayer dielectric layer disposed over a frontside of the second source/drain region.

In another exemplary embodiment, as may be combined with the preceding paragraphs, the semiconductor structure may further include one or more gate stacks and gate spacers surrounding the one or more gate stacks, where the second source/drain region is formed of epitaxial layers which extend toward the one or more gate stacks underneath the gate spacers.

In another embodiment, a nanosheet transistor structure includes an n-type source/drain region having diamond-shaped sidewalls and a p-type source/drain region having trench-confined sidewalls, where at least one of the n-type source/drain region and the p-type source/drain region is disposed over a placeholder layer.

The nanosheet transistor structure advantageously has reduced susceptibility to etch-out of the p-type source/drain region during channel release processing for nanosheet channel layers in a nanosheet stack, where the p-type source/drain region and sacrificial layers in the nanosheet stack are formed of a same material, such as SiGe.

In another exemplary embodiment, as may be combined with the preceding paragraphs, the p-type source/drain region and the placeholder layer may each be formed of SiGe, where a first Ge percentage of the p-type source/drain region is greater than a second Ge percentage of the placeholder layer.

In another exemplary embodiment, as may be combined with the preceding paragraphs, the n-type source/drain region may be disposed over the placeholder layer, and the nanosheet transistor structure may further include a backside contact to the p-type source/drain region. The nanosheet transistor structure may further include a dielectric liner disposed over shallow trench isolation regions surrounding a portion of sidewalls of the backside contact.

In another exemplary embodiment, as may be combined with the preceding paragraphs, the nanosheet transistor structure may further include one or more gate stacks and gate spacers surrounding the one or more gate stacks, wherein the p-type source/drain region includes epitaxial layers which extend toward the one or more gate stacks underneath the gate spacers.

In another embodiment, an integrated circuit includes a nanosheet transistor structure including an n-type source/drain region having diamond-shaped sidewalls and a p-type source/drain region having trench-confined sidewalls, where at least one of the n-type source/drain region and the p-type source/drain region is disposed over a placeholder layer.

The nanosheet transistor structure of the integrated circuit advantageously has reduced susceptibility to etch-out of the p-type source/drain region during channel release processing for nanosheet channel layers in a nanosheet stack, where the p-type source/drain region and sacrificial layers in the nanosheet stack are formed of a same material, such as SiGe.

In another exemplary embodiment, as may be combined with the preceding paragraphs, the p-type source/drain region and the placeholder layer may each be formed of SiGe, where a first Ge percentage of the p-type source/drain region is greater than a second Ge percentage of the placeholder layer.

In another exemplary embodiment, as may be combined with the preceding paragraphs, the n-type source/drain region may be disposed over the placeholder layer, and the integrated circuit may further include a backside contact to the p-type source/drain region.

In another exemplary embodiment, as may be combined with the preceding paragraphs, the integrated circuit may further include a dielectric liner disposed over shallow trench isolation regions surrounding a portion of sidewalls of the backside contact.

In another exemplary embodiment, as may be combined with the preceding paragraphs, the nanosheet transistor structure may further include one or more gate stacks and gate spacers surrounding the one or more gate stacks, where the p-type source/drain region includes epitaxial layers which extend toward the one or more gate stacks underneath the gate spacers.

### BRIEF DESCRIPTION OF THE DRAWINGS

FIG. 1A depicts a first cross-sectional view of a semiconductor structure following patterning of a nanosheet stack, formation of shallow trench isolation regions, formation and patterning of dummy gate structures, formation of gate spacers and a bottom dielectric insulator, nanosheet recess, indent of sacrificial layers of the nanosheet stack, and formation of inner spacers, according to an embodiment of the invention.

FIG. 1B depicts a second cross-sectional view of semiconductor structure following the patterning of the nanosheet stack, the formation of the shallow trench isolation regions, the formation and patterning of the dummy gate structures, the formation of the gate spacers and the bottom dielectric insulator, the nanosheet recess, the indent of the sacrificial layers of the nanosheet stack, and the formation of the inner spacers, according to an embodiment of the invention.

FIG. 1C depicts a top-down view showing where the first and second cross-sectional views of FIGS. 1A and 1B are taken, according to an embodiment of the invention.

FIG. 2A depicts a first cross-sectional view of the structure of FIGS. 1A-1C following formation of a protection liner and placeholder layers, according to an embodiment of the invention.

FIG. 2B depicts a second cross-sectional view of the structure of FIGS. 1A-1C following the formation of the protection liner and the placeholder layers, according to an embodiment of the invention.

FIG. 3A depicts a first cross-sectional view of the structure of FIGS. 2A and 2B following removal of the protection liner, according to an embodiment of the invention.

FIG. 3B depicts a second cross-sectional view of the structure of FIGS. 2A and 2B following the removal of the protection liner, according to an embodiment of the invention.

FIG. 4A depicts a first cross-sectional view of the structure of FIGS. 3A and 3B following formation and patterning of a liner and following formation of source/drain regions for n-type transistors, according to an embodiment of the invention.

FIG. 4B depicts a second cross-sectional view of the structure of FIGS. 3A and 3B following the formation and patterning of the liner and following the formation of the source/drain regions for the n-type transistors, according to an embodiment of the invention.

FIG. 5A depicts a first cross-sectional view of the structure of FIGS. 4A and 4B following formation of an interlayer dielectric layer, according to an embodiment of the invention.

FIG. 5B depicts a second cross-sectional view of the structure of FIGS. 4A and 4B following the formation of the interlayer dielectric layer, according to an embodiment of the invention.

FIG. 6A depicts a first cross-sectional view of the structure of FIGS. 5A and 5B following formation of a gate stack and self-aligned contact capping layer, according to an embodiment of the invention.

FIG. 6B depicts a second cross-sectional view of the structure of FIGS. 5A and 5B following the formation of the gate stack and the self-aligned contact capping layer, according to an embodiment of the invention.

FIG. 7A depicts a first cross-sectional view of the structure of FIGS. 6A and 6B following formation of p-type transistor source/drain trenches, according to an embodiment of the invention.

FIG. 7B depicts a second cross-sectional view of the structure of FIGS. 6A and 6B following the formation of the p-type transistor source/drain trenches, according to an embodiment of the invention.

FIG. 8A depicts a first cross-sectional view of the structure of FIGS. 7A and 7B following removal of portions of the interlayer dielectric layer utilizing a diluted hydrofluoric acid clean, according to an embodiment of the invention.

FIG. 8B depicts a second cross-sectional view of the structure of FIGS. 7A and 7B following the removal of portions of the interlayer dielectric layer utilizing the diluted hydrofluoric acid clean, according to an embodiment of the invention.

FIG. 9A depicts a first cross-sectional view of the structure of FIGS. 8A and 8B following removal of the liner layer and lateral etching of the nanosheet channel layers, according to an embodiment of the invention.

FIG. 9B depicts a second cross-sectional view of the structure of FIGS. 8A and 8B following the removal of the liner layer and the lateral etching of the nanosheet channel layers, according to an embodiment of the invention.

FIG. 10A depicts a first cross-sectional view of the structure of FIGS. 9A and 9B following formation of source/drain regions for p-type transistors, according to an embodiment of the invention.

FIG. 10B depicts a second cross-sectional view of the structure of FIGS. 9A and 9B following the formation of the source/drain regions for the p-type transistors, according to an embodiment of the invention.

FIG. 11A depicts a first cross-sectional view of the structure of FIGS. 10A and 10B following formation of contact trenches for the source/drain regions for the n-type transistors, according to an embodiment of the invention.

FIG. 11B depicts a second cross-sectional view of the structure of FIGS. 10A and 10B following the formation of the contact trenches for the source/drain regions for the n-type transistors, according to an embodiment of the invention.

FIG. 12A depicts a first cross-sectional view of the structure of FIGS. 11A and 11B following formation of middle-of-line contacts, according to an embodiment of the invention.

FIG. 12B depicts a second cross-sectional view of the structure of FIGS. 11A and 11B following the formation of the middle-of-line contacts, according to an embodiment of the invention.

FIG. 13A depicts a first cross-sectional view of the structure of FIGS. 12A and 12B following patterning of an organic planarization layer and recess of exposed ones of the middle-of-line contacts, according to an embodiment of the invention.

FIG. 13B depicts a second cross-sectional view of the structure of FIGS. 12A and 12B following the patterning of the organic planarization layer and the recess of the exposed ones of the middle-of-line contacts, according to an embodiment of the invention.

FIG. 14A depicts a first cross-sectional view of the structure of FIGS. 13A and 13B following formation of MOL contacts, via and metallization layers, back-end-of-line interconnects, and bonding to a carrier wafer, according to an embodiment of the invention.

FIG. 14B depicts a second cross-sectional view of the structure of FIGS. 13A and 13B following the formation of the MOL contacts, the via and metallization layers, the back-end-of-line interconnects, and the bonding to the carrier wafer, according to an embodiment of the invention.

FIG. 15A depicts a first cross-sectional view of the structure of FIGS. 14A and 14B following a wafer flip and removal of the substrate, according to an embodiment of the invention.

FIG. 15B depicts a second cross-sectional view of the structure of FIGS. 14A and 14B following the wafer flip and the removal of the substrate, according to an embodiment of the invention.

FIG. 16A depicts a first cross-sectional view of the structure of FIGS. 15A and 15B following formation of a backside interlayer dielectric layer, patterning of a backside contact trench in the backside interlayer dielectric layer, and removal of a placeholder layer exposed by the backside contact trench, according to an embodiment of the invention.

FIG. 16B depicts a second cross-sectional view of the structure of FIGS. 15A and 15B following the formation of the backside interlayer dielectric layer, the patterning of the backside contact trench in the backside interlayer dielectric layer, and the removal of the placeholder layer exposed by the backside contact trench, according to an embodiment of the invention.

FIG. 17A depicts a first cross-sectional view of the structure of FIGS. 16A and 16B following formation of a backside contact and backside interconnects, according to an embodiment of the invention.

FIG. 17B depicts a second cross-sectional view of the structure of FIGS. 16A and 16B following the formation of the backside contact and the backside interconnects, according to an embodiment of the invention.

FIG. 18 depicts a cross-sectional view of a structure including a sacrificial layer between nanosheet channel layers, box-shaped inner spacers, and source/drain regions, according to an embodiment of the invention.

FIG. 19 depicts a cross-sectional view of a structure including a sacrificial layer between nanosheet channel layers, half-moon shaped inner spacers, and source/drain regions, according to an embodiment of the invention.

FIG. 20 shows an integrated circuit comprising one or more semiconductor structures having source/drain regions with different sidewall shapes, according to an embodiment of the invention.

### DETAILED DESCRIPTION

Illustrative embodiments of the invention may be described herein in the context of illustrative methods for forming semiconductor structures having source/drain regions with different sidewall shapes, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

As described above, the use of stacked nanosheet channels provides a technique useful for reducing the size of field-effect transistors (FETs). A general process flow for formation of a nanosheet stack involves removing sacrificial layers, which may be formed of silicon germanium (SiGe), between sheets of channel material, which may be formed of silicon (Si). Removal of the SiGe sacrificial layers, however, can lead to undesirable “etch-out” of source/drain regions (e.g., source/drain regions for p-type FETs or pFETs) which comprise SiGe epitaxial layers.

Illustrative embodiments provide techniques for forming source/drain regions “last” (e.g., after a channel release or removal of sacrificial layers of a nanosheet stack) which avoids the undesirable etch-out of the source/drain regions. In particular, pFET source/drain epitaxial layers formed of doped SiGe such as boron-doped SiGe (SiGe:B) are formed after the channel release which may involve removal of sacrificial SiGe nanosheet layers. This results in different-shaped source/drain regions for n-type FETs (nFETs) and pFETs. nFET source/drain regions, for example, may have diamond-shaped sidewalls since they may be epitaxially grown in an unconstrained fashion, while pFET source/drain regions have angled sidewalls since they are epitaxially grown in confined trenches.

In some embodiments, a semiconductor structure includes nFET source/drain regions with diamond-shaped sidewalls and pFET source/drain regions with angled sidewalls confined by trenches. At least some of the nFET and pFET source/drain regions may be formed over placeholder layers. The semiconductor structure may also include a backside contact formed to a first one of the pFET source/drain regions, where residual frontside contact to the first pFET source/drain region remains. A local interconnect may be formed over the recessed or removed frontside contact to the first pFET source/drain region, the local interconnect extending horizontally to connect to a frontside contact for an nFET source/drain region. In some embodiments, a dielectric liner is formed over shallow trench isolation (STI) regions surrounding the pFET source/drain regions and the backside contacts to the pFET source drain regions. The dielectric liner may be a different material than that used for gate spacers surrounding gate stacks of the semiconductor structure. The pFET source/drain regions and the placeholder layers may both be formed of SiGe, where a germanium percentage (Ge %) of the pFET source/drain regions is higher than a Ge % of the placeholder layers. The pFET source/drain regions may extend towards the gate stack under the gate spacers.

A method of forming a semiconductor structure includes forming and patterning a nanosheet stack of alternating sacrificial and nanosheet channel layers over a substrate, forming and patterning dummy gate structures over the nanosheet stack, where the dummy gate structures include dummy gate layers and gate spacers, and forming a bottom dielectric insulator (BDI) layer. The sacrificial layers of the nanosheet stack are then indented, followed by formation of inner spacers in the indent regions. A protection liner is then formed on sidewalls of the gate spacers, where the protection liner and the gate spacers are different materials. The BDI layer is then opened and the substrate is etched to form backside contact placeholder trenches. Backside contact placeholder layers are then formed in the backside contact placeholder trenches, followed by removal of the protection liner. An additional protection liner is then formed over the structure, and the additional protection liner is removed from regions of the structure where nFETs are to be formed. nFET source/drain regions are then formed. An interlayer dielectric (ILD) layer is then formed, followed by forming pFET sourced/drain trenches in the ILD layer where pFET source/drain regions are to be formed. The additional protection liner is then selectively removed to reveal the nanosheet channel layers adjacent the pFET source/drain trenches and underlying backside contact placeholder layers. pFET source/drain regions are then formed in the pFET source/drain trenches. Frontside nFET and pFET source/drain region contacts are then formed, followed by pFET and nFET contact metallization. Frontside contacts to ones of the pFET source/drain regions to which backside contacts will be formed are then recessed or removed. The backside contacts to such pFET source/drain regions are then formed.

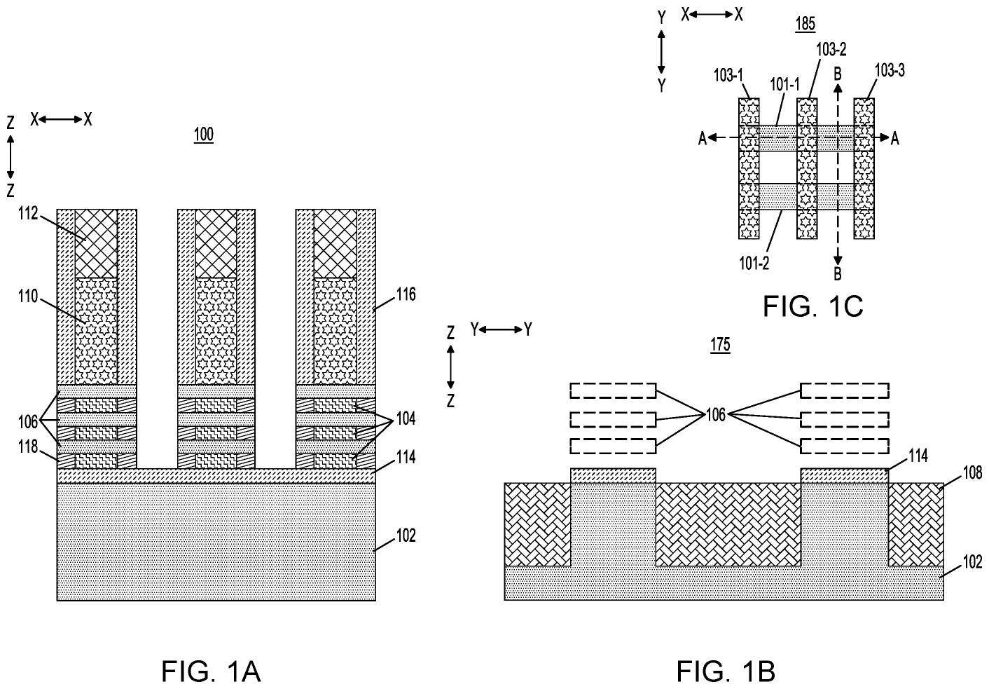

FIGS. 1A-17B show a process flow for forming source/drain regions after a channel release of nanosheet channel layers of a nanosheet stack. This process flow advantageously avoids epitaxial etch-out of source/drain regions formed of a same material as sacrificial layers of the nanosheet stack.

FIGS. 1A-1C show different views of a semiconductor structure. FIG. 1A shows a first cross-sectional view 100 of the semiconductor structure, and FIG. 1B shows a second cross-sectional view 175 of the semiconductor structure. FIG. 1C shows a top-down view 185 illustrating where the first cross-sectional view 100 of FIG. 1A and the second cross-sectional view 175 of FIG. 1B are taken. FIG. 1C shows active regions 101-1 and 101-2 (collectively, active regions 101) and gate regions 103-1, 103-2 and 103-3 (collectively, gate regions 103). In some embodiments, the active region 101-1 is for p-type field-effect transistors (pFETs), while the active region 101-2 is for n-type field-effect transistors (nFETs). The first cross-sectional view 100 of FIG. 1A is taken along the line A-A shown in the top-down view 185 of FIG. 1C (e.g., along the active region 101-1 and across the gate regions 103). The second cross-sectional view 175 of FIG. 1B is taken along the line B-B shown in the top-down view 185 of FIG. 1C (e.g., between the gate regions 103-2 and 103-3 and across the active regions 101).

The semiconductor structure of FIGS. 1A-1C includes a substrate 102, a nanosheet stack including alternating sacrificial layers 104 and nanosheet channel layers 106, STI regions 108, a dummy gate layer 110, a hard mask layer 112, a BDI layer 114, gate spacers 116, and inner spacers 118.

The substrate 102 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. The substrate 102 may have a height (in direction Z) and widths (in directions X/Y) which vary as needed based on the type of structures to be formed.

The sacrificial layers 104 may be formed of SiGe. Each of the sacrificial layers 104 may have a thickness (in direction Z) in the range of 5-15 nm.

The nanosheet channel layers 106 will provide channels for transistors in a transistor structure. The nanosheet channel layers 106 may be formed of Si or another suitable material (e.g., a material similar to that used for the substrate 102). Each of the nanosheet channel layers 106 may have a thickness (in direction Z) in the range of 5-15 nm. It should be noted that, in FIG. 1B, the nanosheet channel layers 106 are shown in dashed outline to highlight the projection effect illustrating, in this view, where the nanosheet channel layers 106 are looking into the page.

The STI regions 108 may be formed of a dielectric material such as silicon dioxide (SiO₂), silicon oxycarbide (SiOC), silicon oxynitride (SiON), etc. The STI regions 108 may have a height (in direction Z) in the range of 10 to 200 nm.

The dummy gate layer 110 may be formed of amorphous silicon (a-Si), amorphous silicon germanium (a-SiGe) over a thin SiO₂ or titanium nitride (TiN) layer, or another suitable material.

The hard mask layer 112 may be formed of silicon nitride (SiN), a multi-layer of SiN and SiO₂, or another suitable material. The hard mask layer 112 may have a height (in direction Z) in the range of 10 nm or larger, and a width (in direction X) matching that of the underlying dummy gate layer 110 (e.g., which may be patterned to have a width in the range of 10-10 nnm).

The BDI layer 114 and the gate spacers 116 may be formed of silicon boron carbide nitride (SiBCN) or another suitable material such as SiN, SiOC, silicon oxycarbonitride (SiOCN), etc. The BDI layer 114 may have a thickness (in direction Z) in the range of 4 to 10 nm. The gate spacers 116 may have a thickness (in direction X) in the range of 4 to 10 nm.

The inner spacers 118 may be formed of SiN, SiBCN, SiOCN, SiC, SiOC, or another suitable material.

The semiconductor structure of FIGS. 1A-1C may be formed by depositing the nanosheet stack (e.g., the sacrificial layers 104 and the nanosheet channel layers 106) over the substrate 102. The nanosheet stack may then be patterned (e.g., using lithographic processing), followed by fill with material of the STI regions 108 and recess of the material of the STI regions 108. The dummy gate layer 110 is then patterned using the hard mask layer 112, followed by an etch that removes a sacrificial layer (not shown, but which may be formed of SiGe with a different percentage of Ge than the sacrificial layers 104) in the area where the BDI layer 114 is formed. Material for the BDI layer 114 and the gate spacers 116 is then formed. An indent etch is then performed to indent the sacrificial layers 104. The inner spacers 118 are then formed in the indent regions. The depth of the indent etch (in direction X) may be in the range of 5-9 nm.

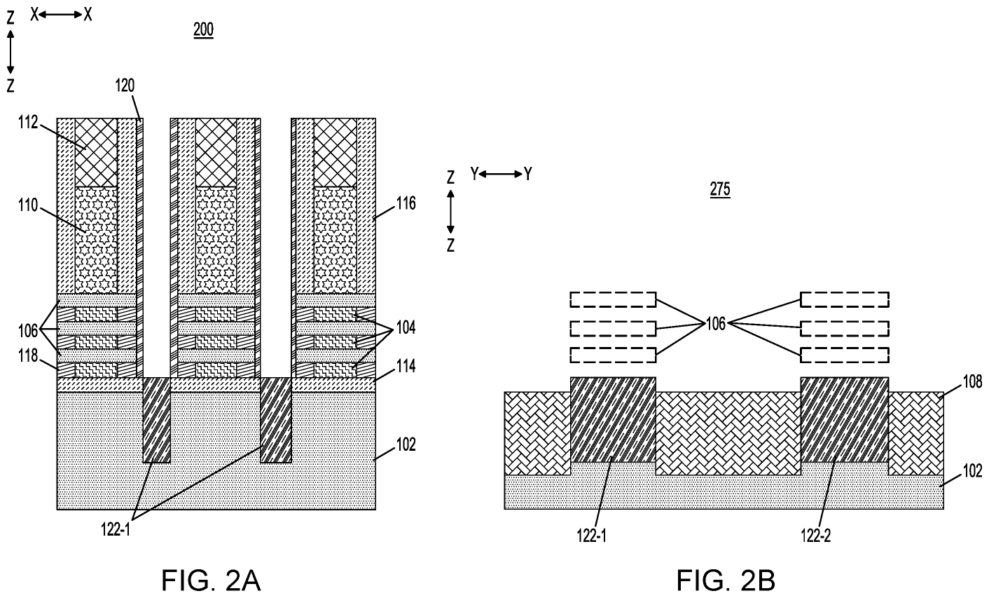

FIGS. 2A and 2B show first and second cross-sectional views 200 and 275, respectively, of the structure of FIGS. 1A-1C following formation of a protection liner 120 and placeholder layers 122-1 and 122-2 (collectively, placeholder layers 122). The first cross-sectional view 200 of FIG. 2A is taken along the line A-A shown in the top-down view 185 of FIG. 1C, and the second cross-sectional view 275 of FIG. 2B is taken along the line B-B shown in the top-down view 185 of FIG. 1C.

The protection liner 120 may be formed on sidewalls of the gate spacers 116, the nanosheet channel layers 106 and the inner spacers 118 above the BDI layer 114. The protection liner 120 may be formed of SiN or another suitable material such as SiBCN, SiCOH, SiNCH, etc. The protection liner 120 may have a thickness (in direction X) in the range of 1-2 nm. Following formation of the protection liner 120, etching is performed to open the BDI layer 114 and form placeholder cavity trenches through the substrate 102. The placeholder cavity trenches may be formed to a depth (in direction Z) in the substrate 102 in the range of 50-70 nm.

The placeholder layers 122 are then formed in the placeholder cavity trenches. The placeholder layers 122 may be formed of SiGe or another suitable material such as lattice matched rare earth oxides. The placeholder layers 122 may be formed using an epitaxial growth process. In the figures, the placeholder layers 122-1 are formed in pFET regions (e.g., across active region 101-1 shown in the top-down view 185 of FIG. 1C), while the placeholder layers 122-2 are formed in nFET regions (e.g., corresponding to the active region 101-2 shown in the top-down view 185 of FIG. 1C).

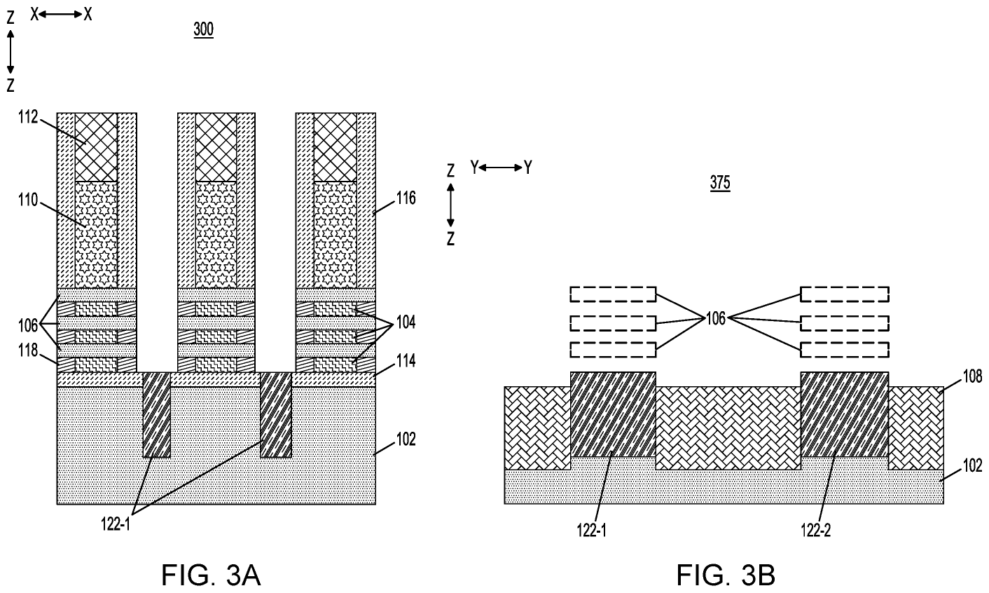

FIGS. 3A and 3B show first and second cross-sectional views 300 and 375, respectively, of the structure of FIGS. 2A and 2B following removal of the protection liner 120. The first cross-sectional view 300 of FIG. 3A is taken along the line A-A shown in the top-down view 185 of FIG. 1C, and the second cross-sectional view 375 of FIG. 3B is taken along the line B-B shown in the top-down view 185 of FIG. 1C. The protection liner 120 may be removed using any suitable etch process, such as atomic layer etching (ALE), anisotropic etching, etc.

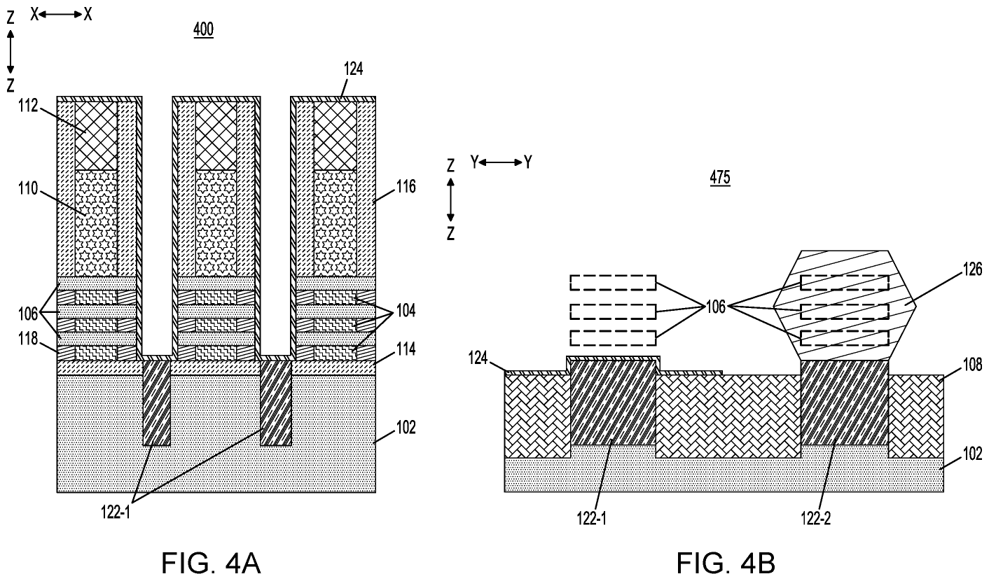

FIGS. 4A and 4B show first and second cross-sectional views 400 and 475, respectively, of the structure of FIGS. 3A and 3B following formation and patterning of a protection liner 124 and following formation of nFET source/drain regions 126. The first cross-sectional view 400 of FIG. 4A is taken along the line A-A shown in the top-down view 185 of FIG. 1C, and the second cross-sectional view 475 of FIG. 4B is taken along the line B-B shown in the top-down view 185 of FIG. 1C.

The protection liner 124 may be blanket deposited over the structure, followed by patterning such that the protection liner 124 is removed from the nFET regions of the structure. The protection liner 124 protects the pFET regions of the structure during formation of the nFET source/drain regions 126. The protection liner 124 may be formed of a different material than the gate spacers 116, enabling the protection liner 124 to be removed or etched selective to the gate spacers 116. For example, the gate spacers 116 may be formed of SiOC while the protection liner 124 is formed of SiN. Various other combinations of materials may be used for the gate spacers 116 and the protection liner 124. The protection liner 124 may have a uniform thickness in the range of 2-3 nm.

The nFET source/drain regions 126 may be formed using an epitaxial growth process. The nFET source/drain regions 126 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb). In some embodiments, the epitaxy process used to form the nFET source/drain regions 126 comprises in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial Si, SiGe, Ge, and/or carbon doped silicon (Si: C) can be doped during deposition (in-situ doped) by adding dopants, such as n-type dopants (e.g., phosphorus or arsenic). The dopant concentration in the source/drain can range from 1×10¹⁹ cm⁻³ to 3×10²¹ cm⁻³, or preferably between 2×10²⁰ cm⁻³ to 3×10²¹ cm⁻³. The nFET source/drain regions 126 may have diamond-shaped sidewalls as illustrated.

It should be noted that while FIGS. 4A and 4B (and subsequent figures) illustrate a process flow whereby source/drain regions for nFETs are formed first, this is not a requirement. In other embodiments, the protection liner 124 may be formed to protect the nFET regions and expose the pFET regions, such that the source/drain regions for pFETs are formed first.

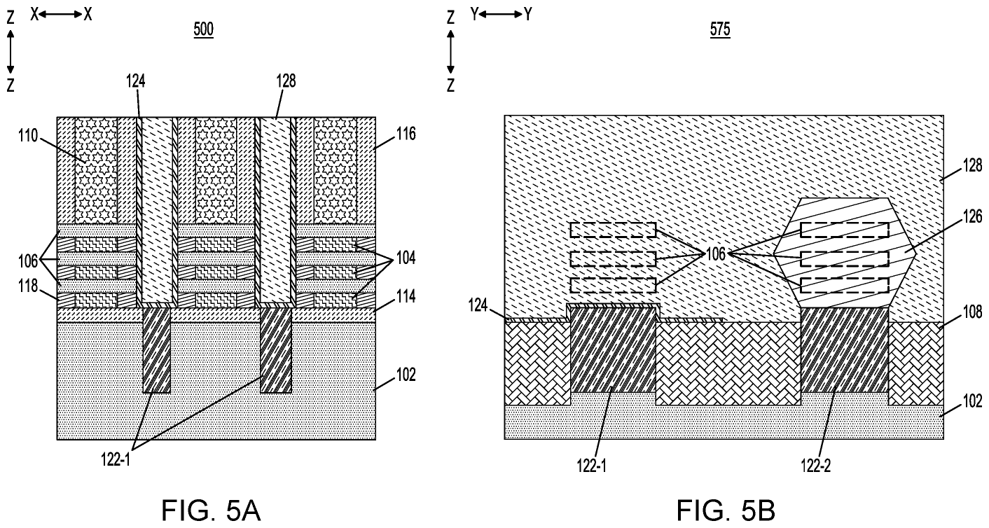

FIGS. 5A and 5B show first and second cross-sectional views 500 and 575, respectively, of the structure of FIGS. 4A and 4B following formation of an ILD layer 128. The first cross-sectional view 500 of FIG. 5A is taken along the line A-A shown in the top-down view 185 of FIG. 1C, and the second cross-sectional view 575 of FIG. 5B is taken along the line B-B shown in the top-down view 185 of FIG. 1C.

The ILD layer 128 may be formed by filling the structure with an ILD material, followed by planarization (e.g., using chemical mechanical planarization (CMP)) to result in the structure shown in FIGS. 5A and 5B. The planarization of the ILD layer 128 removes the hard mask layer 112 and portions of the protection liner 124 as illustrated. The ILD layer 128 may be formed of any suitable isolating material, such as SiO₂, SiOC, SiON, etc.

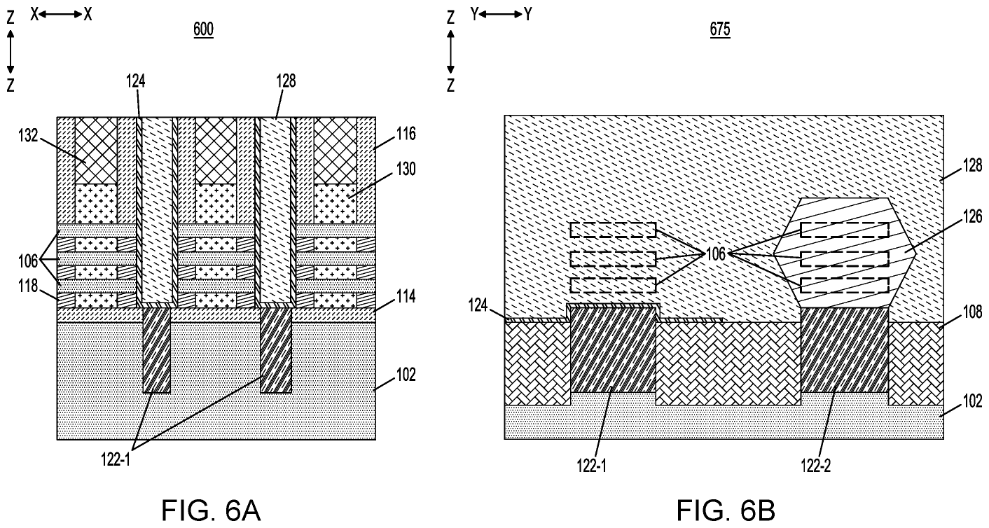

FIGS. 6A and 6B show first and second cross-sectional views 600 and 675, respectively, of the structure of FIGS. 5A and 5B following formation of a gate stack 130 and a self-aligned contact (SAC) capping layer 132. The first cross-sectional view 600 of FIG. 6A is taken along the line A-A shown in the top-down view 185 of FIG. 1C, and the second cross-sectional view 675 of FIG. 6B is taken along the line B-B shown in the top-down view 185 of FIG. 1C.

The gate stack 130 may be formed using replacement metal gate (RMG) processing. The RMG processing includes removal of the dummy gate layer 110 and the sacrificial layers 104, followed by formation of the gate stack 130.

The gate stack 130 may include a gate dielectric and a gate conductor. The gate dielectric may be conformally deposited in the structure, and may be formed of a high-k material. Examples of high-k materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate dielectric may have a uniform thickness in the range of 1 nm to 3 nm. The gate conductor may include a gate work function metal (WFM) layer and a gate metal layer. The gate WFM layer may be formed of a WFM such as titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. The gate WFM layer may have a uniform thickness in the range of 1 to 10 nm. The gate metal layer may comprise a conductive metal (e.g., tungsten (W)). Advantageously, formation of the gate stack 130 does not cause and damage to pFET source/drain regions (which are not yet formed) due to SiGe etch out.

The SAC capping layer 132 may be formed of SiN, SiBCN, SiOCN, SiOC, etc. The SAC capping layer 132 may have a height (in direction Z) in the range of 10 to 50 nm.

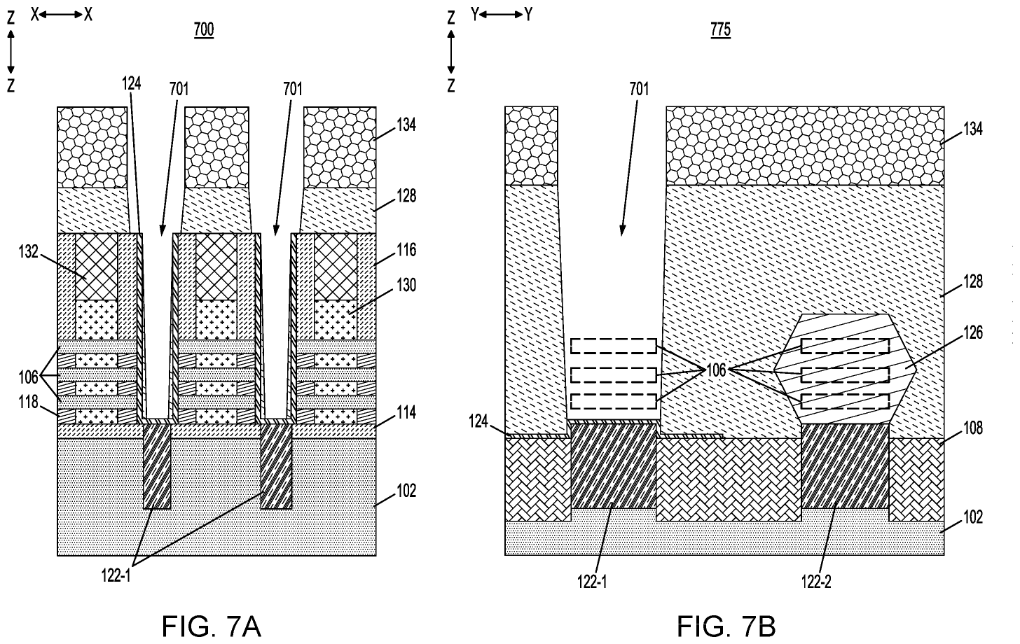

FIGS. 7A and 7B show first and second cross-sectional views 700 and 775, respectively, of the structure of FIGS. 6A and 6B following formation of pFET source/drain trenches 701. The first cross-sectional view 700 of FIG. 7A is taken along the line A-A shown in the top-down view 185 of FIG. 1C, and the second cross-sectional view 775 of FIG. 7B is taken along the line B-B shown in the top-down view 185 of FIG. 1C.

To form the pFET source/drain trenches 701, additional material for the ILD layer 128 may be formed, followed by deposition and patterning of an organic planarization layer (OPL) 134. The ILD layer 128 is then etched in the regions exposed by the patterned OPL 134 to form the pFET source/drain trenches 701.

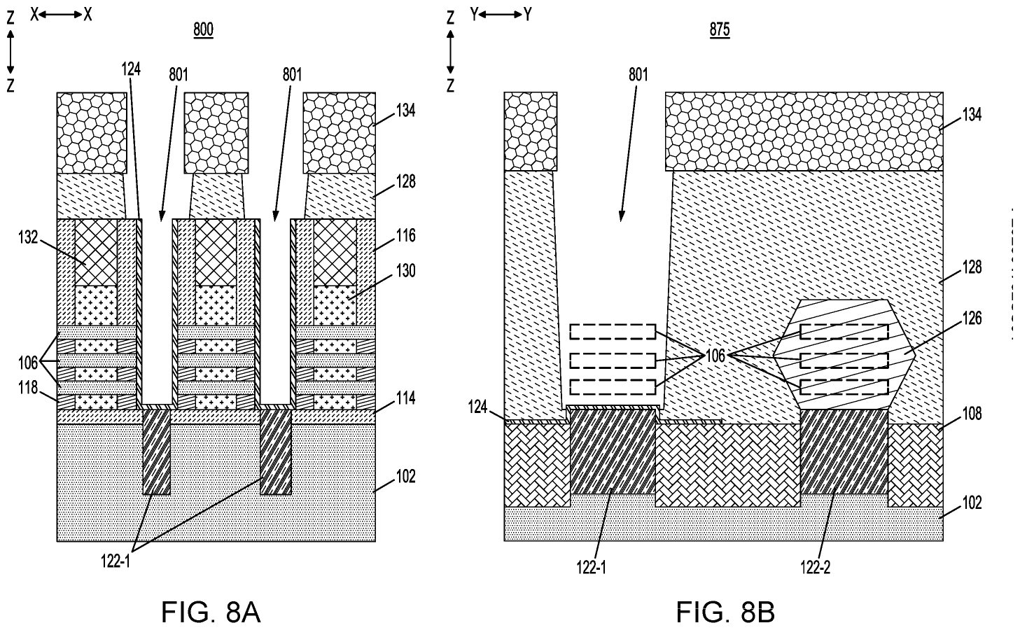

FIGS. 8A and 8B show first and second cross-sectional views 800 and 875, respectively, of the structure of FIGS. 7A and 7B following removal of portions of the ILD layer 128 utilizing a diluted hydrofluoric acid (DHF) clean. The DHF clean removes additional portions of the ILD layer 128, widening the pFET source/drain trenches 701 into the pFET source/drain trenches 801 shown in FIGS. 8A and 8B. The first cross-sectional view 800 of FIG. 8A is taken along the line A-A shown in the top-down view 185 of FIG. 1C, and the second cross-sectional view 875 of FIG. 8B is taken along the line B-B shown in the top-down view 185 of FIG. 1C.

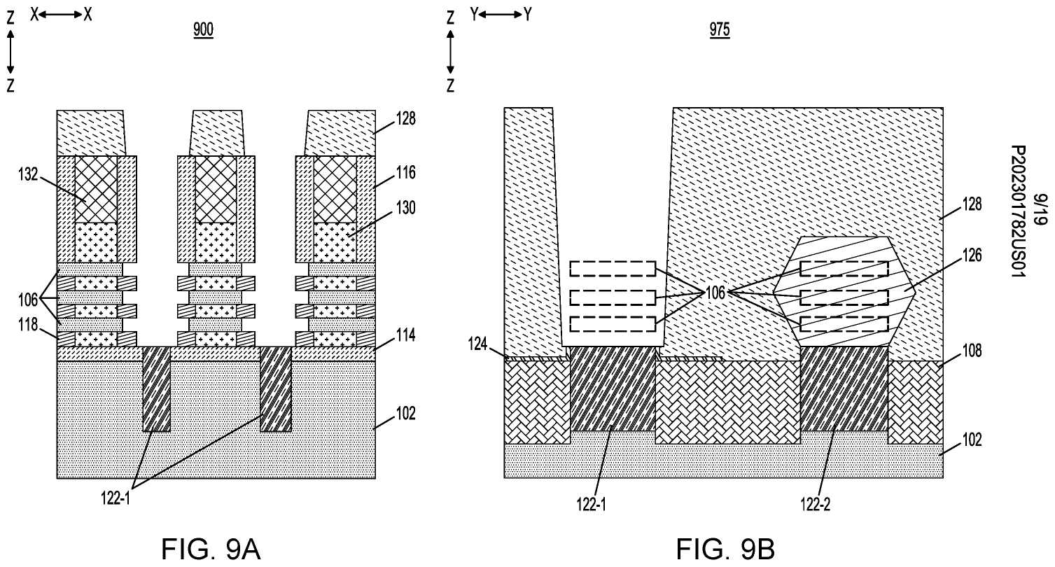

FIGS. 9A and 9B show first and second cross-sectional views 900 and 975, respectively, of the structure of FIGS. 8A and 8B following removal of the protection liner 124 and lateral etching of the nanosheet channel layers 106. The first cross-sectional view 900 of FIG. 9A is taken along the line A-A shown in the top-down view 185 of FIG. 1C, and the second cross-sectional view 975 of FIG. 9B is taken along the line B-B shown in the top-down view 185 of FIG. 1C.

Exposed portions of the protection liner 124 are removed using a selective etch process (e.g., which removes the material of the protection liner 124 selective to that of the gate spacers 116 and the ILD layer 128). This exposes top surfaces of the placeholder layers 122-1. A lateral etching (e.g., lateral channel release) is then performed to remove portions of the nanosheet channel layers 106. The lateral etching may be to a distance (in direction X) that is less than the thickness of the gate spacers 116. The OPL 134 is also removed.

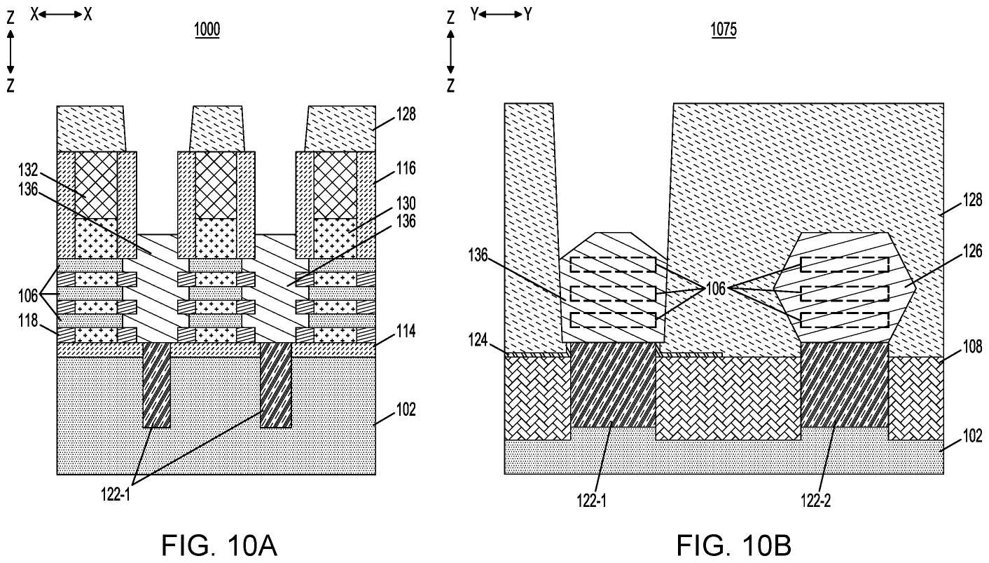

FIGS. 10A and 10B show first and second cross-sectional views 1000 and 1075, respectively, of the structure of FIGS. 9A and 9B following formation of pFET source/drain regions 136. The first cross-sectional view 1000 of FIG. 10A is taken along the line A-A shown in the top-down view 185 of FIG. 1C, and the second cross-sectional view 1075 of FIG. 10B is taken along the line B-B shown in the top-down view 185 of FIG. 1C.

The pFET source/drain regions 136 may be formed using an epitaxial growth process. The pFET source/drain regions 136 may be suitably doped, such as using ion implantation, gas phase doping, plasma doping, plasma immersion ion implantation, cluster doping, infusion doping, liquid phase doping, solid phase doping, etc. P-type dopants may be selected from a group of boron (B), boron fluoride (BF₂), gallium (Ga), indium (In), and thallium (TI). In some embodiments, the epitaxy process used to form the pFET source/drain regions 136 comprises in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial Si, SiGe, Ge, and/or Si: C can be doped during deposition (in-situ doped) by adding dopants, such as p-type dopants (e.g., boron or gallium). The dopant concentration in the source/drain can range from 1×10¹⁹ cm⁻³ to 3×10²¹ cm⁻³, or preferably between 2×10²⁰ cm⁻³ to 3×10²¹ cm⁻³.

In some embodiments, the pFET source/drain regions 136 are formed using a low temperature epitaxial growth process. Advantageously, the pFET source/drain regions 136 can be grown with a high percentage of Ge, as there is no concern about Ge diffusion at this point in the processing. Further, the presence of the underlying placeholder layers 122-1 (e.g., formed of SiGe with a Ge percentage of 25%) and the pFET source/drain regions 136 (e.g., formed with a high Ge percentage) can generate strain.

As noted above, the nFET source/drain regions 126 have diamond-shaped sidewalls (e.g., as they are grown without being confined). The pFET source/drain regions 136 do not have diamond-shaped sidewalls, as their shape is confined by the sidewalls of the pFET source/drain trenches 801 as illustrated.

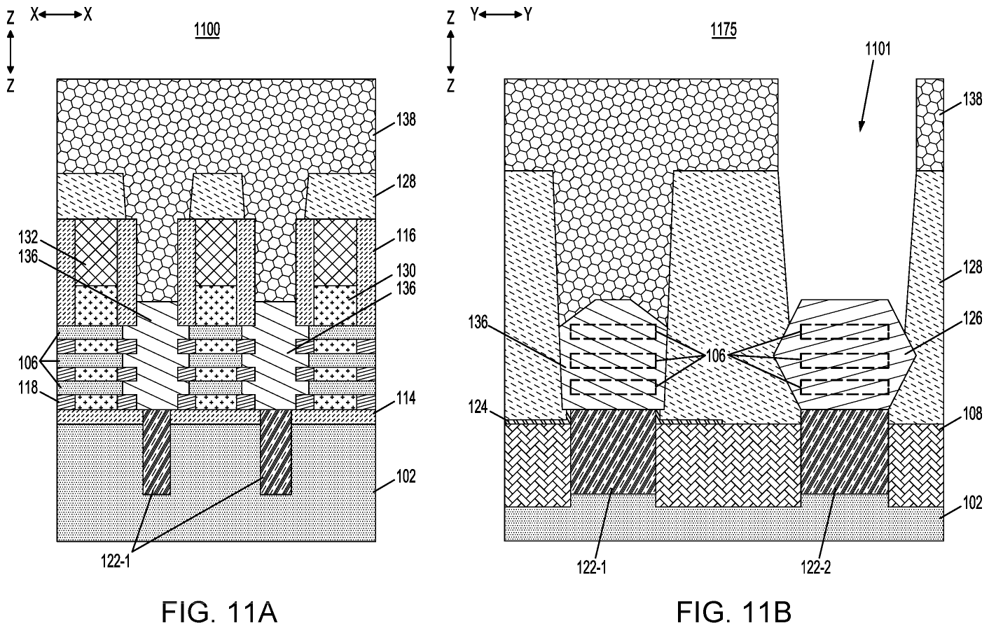

FIGS. 11A and 11B show first and second cross-sectional views 1100 and 1175, respectively, of the structure of FIGS. 10A and 10B following formation of nFET source/drain contact trench 1101. The first cross-sectional view 1100 of FIG. 11A is taken along the line A-A shown in the top-down view 185 of FIG. 1C, and the second cross-sectional view 1175 of FIG. 11B is taken along the line B-B shown in the top-down view 185 of FIG. 1C.

To form the nFET source/drain contact trench 1101, an OPL 138 is formed and patterned over the structure. Portions of the ILD layer 128 exposed by the patterned OPL 138 are then removed using a suitable etch process to expose portions of the nFET source/drain regions 126.

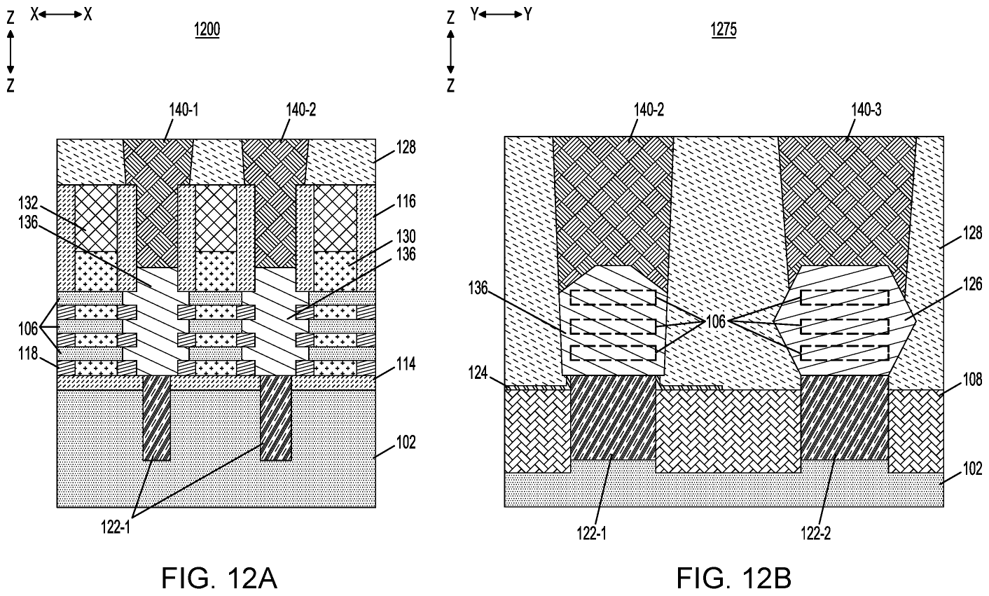

FIGS. 12A and 12B show first and second cross-sectional views 1200 and 1275, respectively, of the structure of FIGS. 11A and 11B following formation of middle-of-line (MOL) contacts 140-1, 140-2 and 140-3. The first cross-sectional view 1200 of FIG. 12A is taken along the line A-A shown in the top-down view 185 of FIG. 1C, and the second cross-sectional view 1275 of FIG. 12B is taken along the line B-B shown in the top-down view 185 of FIG. 1C.

The OPL 138 is removed, followed by formation of the MOL contacts 140-1, 140-2 and 140-3. The MOL contacts 140-1 and 140-2 are formed to connect to the pFET source/drain regions 136, while the MOL contact 140-3 is formed to connect to the nFET source/drain regions 126. The MOL contacts 140-1, 140-2 and 140-3 (collectively, MOL contacts 140) are formed by filling contact trenches with a contact material (e.g., a silicide liner such as titanium (Ti), nickel (Ni), a nickel-platinum alloy (NiPt), a metal adhesion layer such as titanium nitride (TiN), and a low resistance metal fill such as tungsten (W), cobalt (Co), or ruthenium (Ru)).

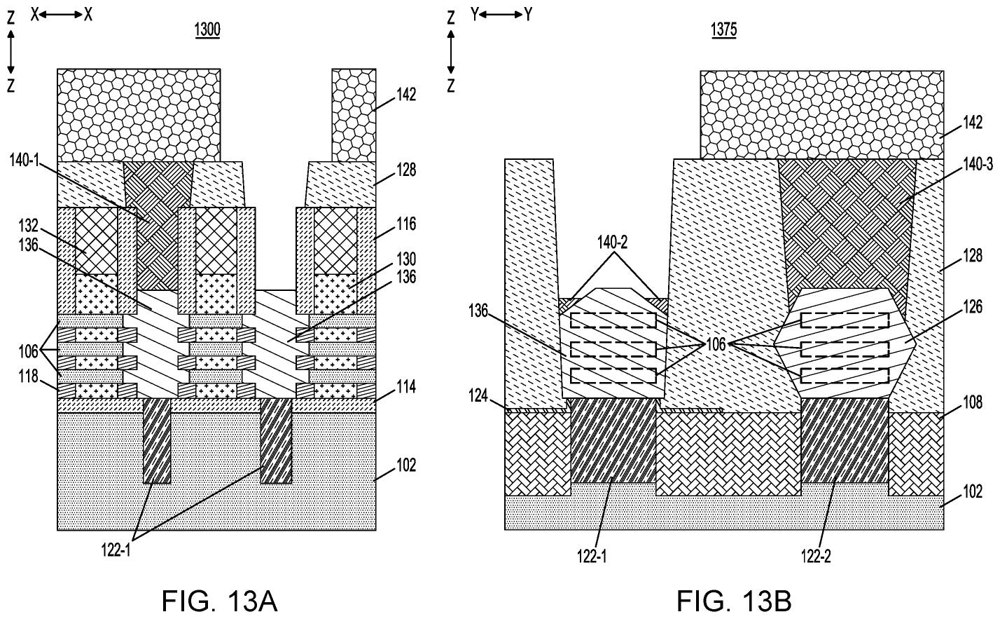

FIGS. 13A and 13B show first and second cross-sectional views 1300 and 1375, respectively, of the structure of FIGS. 12A and 12B following recessing the MOL contact 140-2. The first cross-sectional view 1300 of FIG. 13A is taken along the line A-A shown in the top-down view 185 of FIG. 1C, and the second cross-sectional view 1375 of FIG. 13B is taken along the line B-B shown in the top-down view 185 of FIG. 1C.

An OPL 142 is patterned over the structure to expose the MOL contact 140-2. At least a portion of the MOL contact 140-2 is then recessed or removed. It is permissible for there to be some remainder of the MOL contact 140-2 as shown in FIG. 13B (e.g., at the corners of the pFET source/drain region 136 where the silicide is not easily removed).

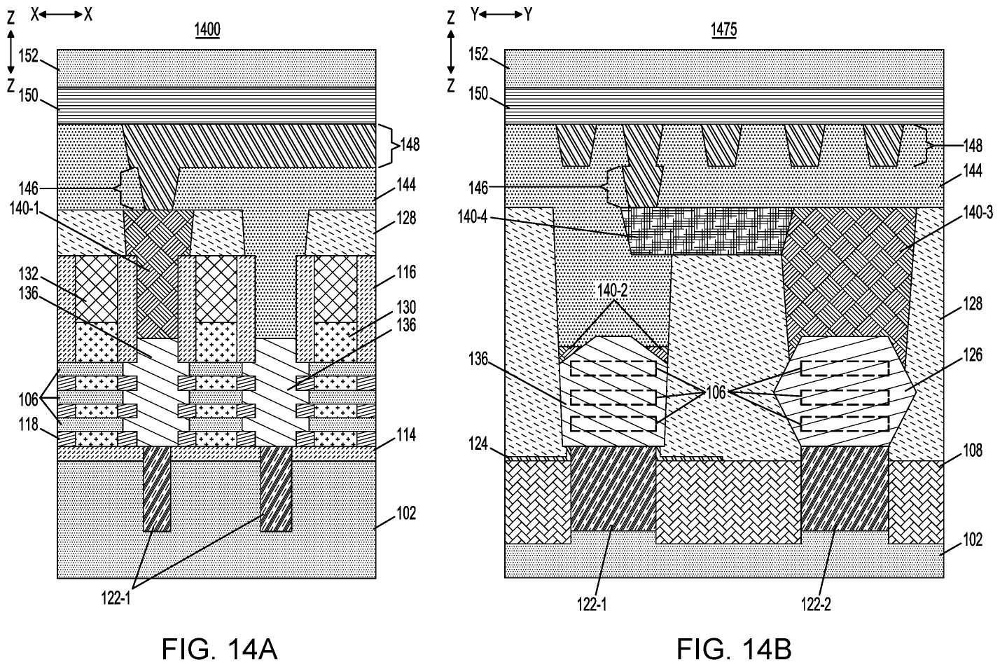

FIGS. 14A and 14B show first and second cross-sectional views 1400 and 1475, respectively, of the structure of FIGS. 13A and 13B following formation of a local interconnect 140-4, ILD layer 144, via layer 146, metallization layer 148, back-end-of-line (BEOL) interconnects 150, and bonding to a carrier wafer 152. The first cross-sectional view 1400 of FIG. 14A is taken along the line A-A shown in the top-down view 185 of FIG. 1C, and the second cross-sectional view 1475 of FIG. 14B is taken along the line B-B shown in the top-down view 185 of FIG. 1C.

The ILD layer 144, which may be formed of materials similar to that of the ILD layer 128, is filled over the structure and planarized (e.g., using CMP), and then patterned to provide an opening where the local interconnect 140-4 is formed. The local interconnect 140-4 extends horizontally and contacts the MOL contact 140-3 as illustrated in FIG. 14B. The local interconnect 140-4 may be formed of similar materials as the MOL contacts 140-1 through 140-3. The ILD layer 144 is then further patterned to provide openings where a via layer 146 and a metallization layer 148 are formed. The via layer 146 and metallization layer 148 may be formed of a metal material such as copper (Cu), cobalt (Co), ruthenium (Ru), TiN, etc., and enable interconnection between the MOL contacts 140-1 and 140-3 (e.g., via the local interconnect 140-4) and the BEOL interconnects 150, which are formed over the structure. The structure is then bonded to a carrier wafer 152, which may be formed of Si or another material similar to that used for the substrate 102.

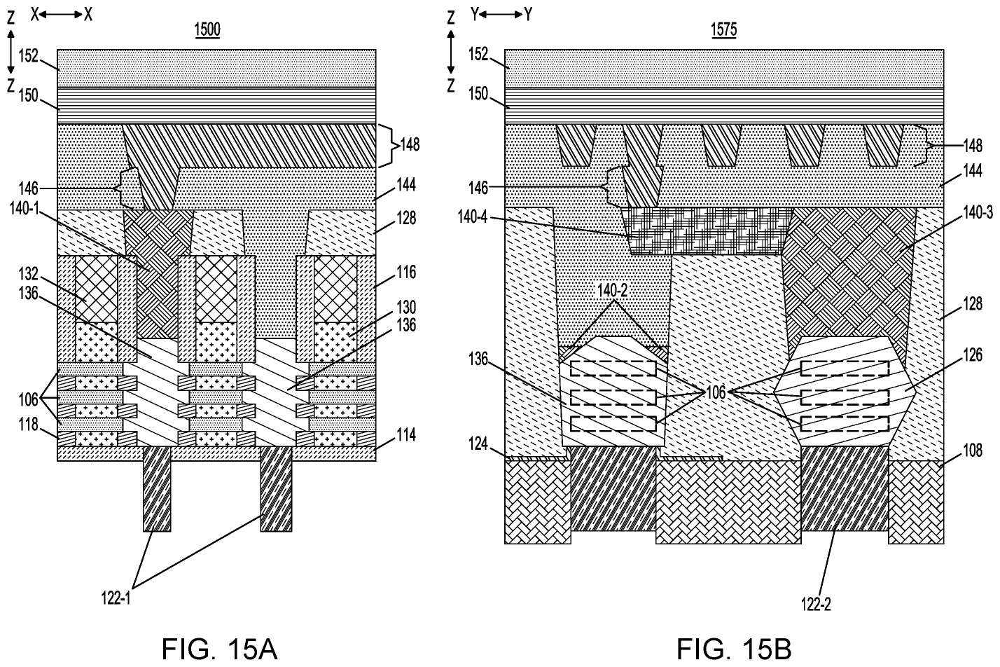

FIGS. 15A and 15B show first and second cross-sectional views 1500 and 1575, respectively, of the structure of FIGS. 14A and 14B following a wafer flip and removal of the substrate 102. The first cross-sectional view 1500 of FIG. 15A is taken along the line A-A shown in the top-down view 185 of FIG. 1C, and the second cross-sectional view 1575 of FIG. 15B is taken along the line B-B shown in the top-down view 185 of FIG. 1C.

The wafer is flipped utilizing the carrier wafer 152, and the substrate 102 is then removed from the backside utilizing a suitable etch process (e.g., reactive-ion etching (RIE)). The etch process removes the substrate 102 while leaving the placeholder layers 122 intact as illustrated.

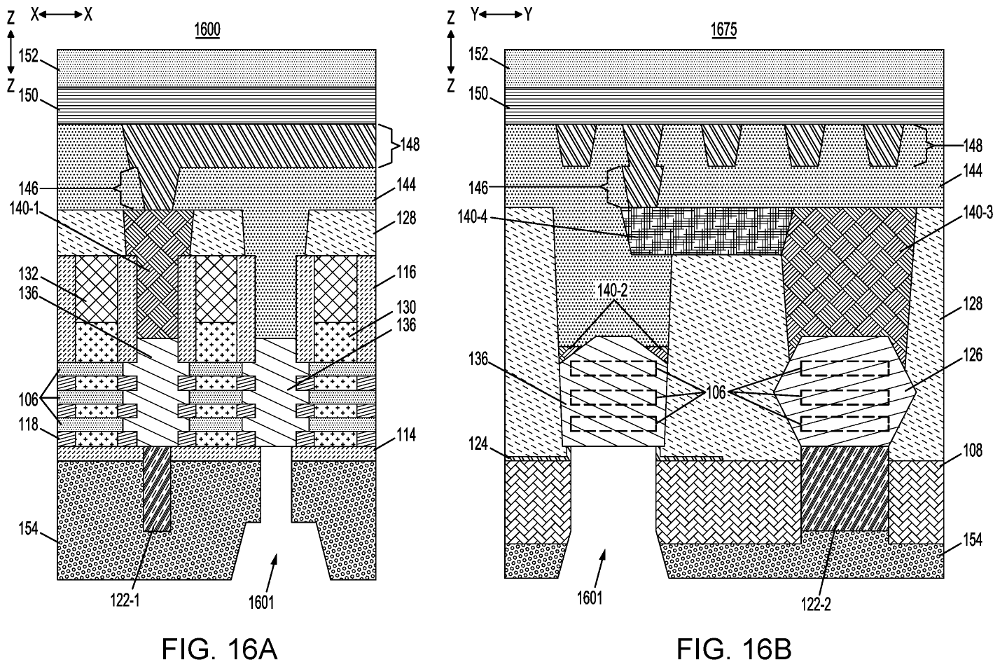

FIGS. 16A and 16B show first and second cross-sectional views 1600 and 1675, respectively, of the structure of FIGS. 15A and 15B following formation and patterning of a backside ILD layer 154, following formation of a backside contact trench 1601 through the backside ILD layer 154, and following removal of the exposed placeholder layer 122-1 to reveal a bottom surface of the pFET source/drain region 136. The first cross-sectional view 1600 of FIG. 16A is taken along the line A-A shown in the top-down view 185 of FIG. 1C, and the second cross-sectional view 1675 of FIG. 16B is taken along the line B-B shown in the top-down view 185 of FIG. 1C.

Material for the backside ILD layer 154 may be filled and then planarized (e.g., using CMP). The backside ILD layer 154 may be formed of similar materials as the ILD layers 128 and 144. The backside ILD layer 154 has a height (in direction Z) which is sufficient to completely cover the placeholder layers 122.

A mask layer (not shown) is then patterned over the backside ILD layer 154, and exposed portions of the backside ILD layer 154 are removed using a suitable etch process so as to form backside contact trench 1601. The placeholder layer 122-1 exposed by the backside contact trench 1601 is then removed using a suitable etch process.

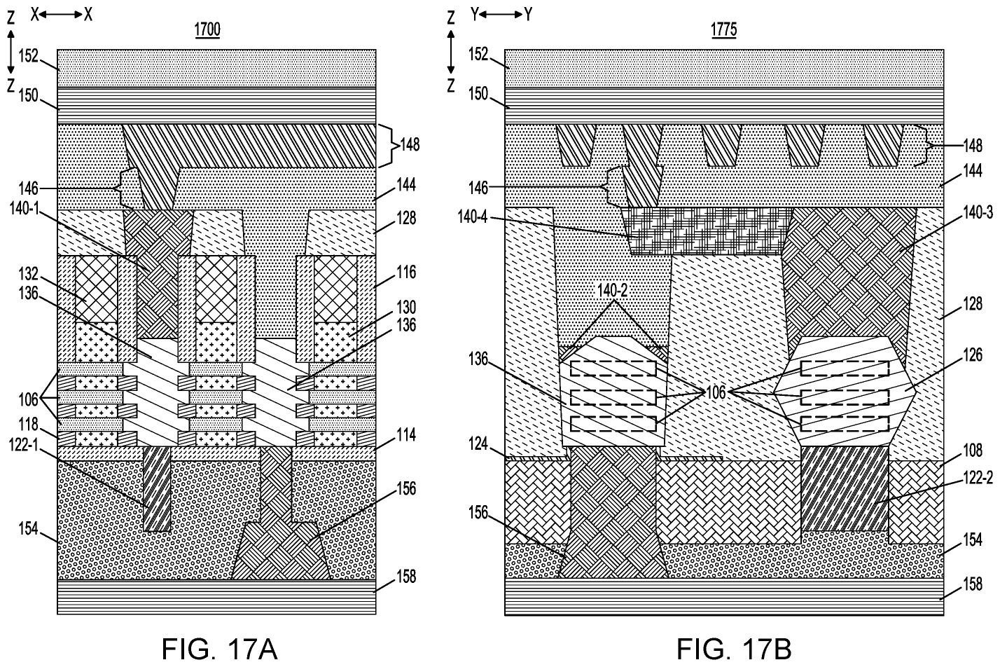

FIGS. 17A and 17B show first and second cross-sectional views 1700 and 1775, respectively, of the structure of FIGS. 16A and 16B following formation of a backside contact 156 and backside interconnects 158. The first cross-sectional view 1700 of FIG. 17A is taken along the line A-A shown in the top-down view 185 of FIG. 1C, and the second cross-sectional view 1775 of FIG. 17B is taken along the line B-B shown in the top-down view 185 of FIG. 1C.

The backside contact 156 is formed in the backside contact trench 1601 and the region exposed by removal of the placeholder layer 122-1. The backside contact 156 may be formed of similar materials as the MOL contacts 140-1 through 140-3 and the local interconnect 140-4. The backside interconnects 158 are then formed.

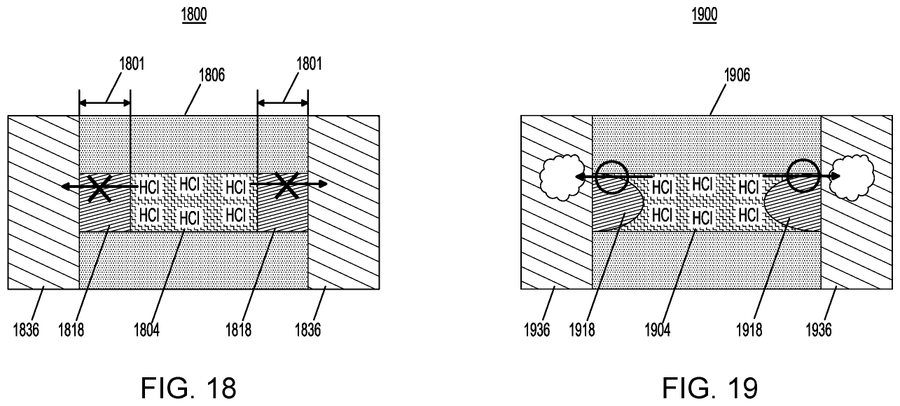

Advantageously, forming the pFET source/drain regions 136 “last” (e.g., after the RMG processing which includes removal of the sacrificial layers 104 as part of a SiGe channel release) can prevent undesirable etch-out of the pFET source/drain regions 136. Such undesirable etch-out of pFET source/drain regions (e.g., formed as SiGe epitaxial layers) is illustrated in FIGS. 18 and 19.

FIG. 18 shows a cross-sectional view 1800 of a structure including a sacrificial layer 1804, nanosheet channel layers 1806, inner spacers 1818, and pFET source/drain regions 1836 which are similar in size and materials as the above-described sacrificial layers 104, nanosheet channel layers 106, inner spacers 118 and pFET source/drain regions 136. Here, the inner spacers 1818 have an ideal box-shape, providing a good shielding (e.g., approximately 6 nm distance 1801) of the pFET source/drain regions 1836 from hydrochloric acid (HCl) which is used in performing a channel release or removal of the sacrificial layer 1804.

FIG. 19 shows a cross-sectional view 1900 of a structure including a sacrificial layer 1904, nanosheet channel layers 1906, inner spacers 1918, and pFET source/drain regions 1936 which are similar in size and materials as the above-described sacrificial layers 104, nanosheet channel layers 106, inner spacers 118 and pFET source/drain regions 136. Here, the inner spacers 1918 have a real-world, non-ideal half-moon shape, where at top and bottom surfaces of the inner spacers 1918 there is no or insufficient shielding of the pFET source/drain regions 1936, such that there is HCl leakage through meniscuses which etches away parts of the pFET source/drain regions 1936.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductor (CMOS) transistors, metal-oxide-semiconductor field-effect transistors (MOSFETs), and/or fin field-effect transistors (FinFETs). By way of non-limiting example, the semiconductor devices can include, but are not limited to CMOS, MOSFET, and FinFET devices, and/or semiconductor devices that use CMOS, MOSFET, and/or FinFET technology.

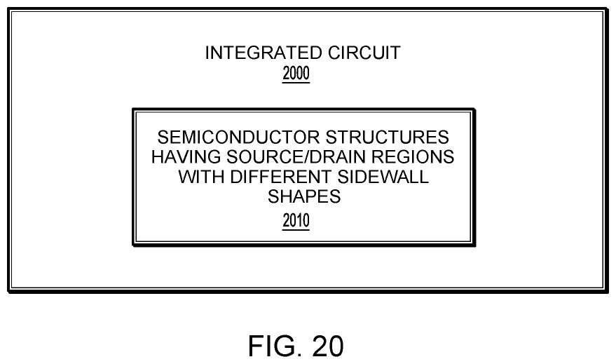

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 20 shows an example integrated circuit 2000 which includes one or more semiconductor structures 2010 having source/drain regions with different sidewall shapes.

In some embodiments, a semiconductor structure includes a first source/drain region having a first sidewall shape and a second source/drain region having a second sidewall shape, the second sidewall shape being different than the first sidewall shape. At least one of the first source/drain region and the second source/drain region is disposed over a placeholder layer.

The first source/drain region may be an n-type source/drain region and the second source/drain region may be a p-type source/drain region. The first sidewall shape may comprise diamond-shaped sidewalls and the second sidewall shape may comprise trench-confined sidewalls. The second source/drain region and the placeholder layer may be formed of SiGe, where a first percentage of Ge in the second source/drain region is greater than a second percentage of Ge in the placeholder layer.

The first source/drain region may be disposed over the placeholder layer, and the semiconductor structure may further include a backside contact to the second source/drain region. The semiconductor structure may further include a dielectric liner disposed over STI regions surrounding a portion of sidewalls of the backside contact. The dielectric liner may be a first material different than a second material of gate spacers surrounding gate stacks of the semiconductor structure. The semiconductor structure may further include residual frontside contact material on a frontside of the second source/drain region. The semiconductor structure may further include a frontside contact on a frontside of the first source/drain region and a local interconnect extending horizontally from the frontside contact to at least a portion of an area of an ILD layer disposed over a frontside of the second source/drain region.

The semiconductor structure may further include one or more gate stacks and gate spacers surrounding the one or more gate stacks, where the second source/drain region is formed of epitaxial layers which extend toward the one or more gate stacks underneath the gate spacers.

In some embodiments, a nanosheet transistor structure includes an n-type source/drain region having diamond-shaped sidewalls and a p-type source/drain region having trench-confined sidewalls, where at least one of the n-type source/drain region and the p-type source/drain region is disposed over a placeholder layer.

The p-type source/drain region and the placeholder layer may each be formed of SiGe, where a first Ge percentage of the p-type source/drain region is greater than a second Ge percentage of the placeholder layer.

The n-type source/drain region may be disposed over the placeholder layer, and the nanosheet transistor structure may further include a backside contact to the p-type source/drain region. The nanosheet transistor structure may further include a dielectric liner disposed over STI regions surrounding a portion of sidewalls of the backside contact.

The nanosheet transistor structure may further include one or more gate stacks and gate spacers surrounding the one or more gate stacks, wherein the p-type source/drain region includes epitaxial layers which extend toward the one or more gate stacks underneath the gate spacers.

In some embodiments, an integrated circuit includes a nanosheet transistor structure including an n-type source/drain region having diamond-shaped sidewalls and a p-type source/drain region having trench-confined sidewalls, where at least one of the n-type source/drain region and the p-type source/drain region is disposed over a placeholder layer.

The p-type source/drain region and the placeholder layer may each be formed of SiGe, where a first Ge percentage of the p-type source/drain region is greater than a second Ge percentage of the placeholder layer.

The n-type source/drain region may be disposed over the placeholder layer, and the integrated circuit may further include a backside contact to the p-type source/drain region.

The integrated circuit may further include a dielectric liner disposed over STI regions surrounding a portion of sidewalls of the backside contact.

The nanosheet transistor structure may further include one or more gate stacks and gate spacers surrounding the one or more gate stacks, where the p-type source/drain region includes epitaxial layers which extend toward the one or more gate stacks underneath the gate spacers.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first source/drain region having a first sidewall shape; and
a second source/drain region having a second sidewall shape, the second sidewall shape being different than the first sidewall shape;
wherein at least one of the first source/drain region and the second source/drain region is disposed over a placeholder layer.

2. The semiconductor structure of claim 1, wherein the first source/drain region comprises an n-type source/drain region and the second source/drain region comprises a p-type source/drain region.

3. The semiconductor structure of claim 2, wherein the first sidewall shape comprises diamond-shaped sidewalls and the second sidewall shape comprises trench-confined sidewalls.

4. The semiconductor structure of claim 2, wherein the second source/drain region and the placeholder layer comprise silicon germanium (SiGe), and wherein a first percentage of germanium (Ge) in the second source/drain region is greater than a second percentage of Ge in the placeholder layer.

5. The semiconductor structure of claim 1, wherein the first source/drain region is disposed over the placeholder layer, and further comprising a backside contact to the second source/drain region.

6. The semiconductor structure of claim 5, further comprising a dielectric liner disposed over shallow trench isolation regions surrounding a portion of sidewalls of the backside contact.

7. The semiconductor structure of claim 6, wherein the dielectric liner comprises a first material different than a second material of gate spacers surrounding gate stacks of the semiconductor structure.

8. The semiconductor structure of claim 5, further comprising residual frontside contact material on a frontside of the second source/drain region.

9. The semiconductor structure of claim 5, further comprising a frontside contact on a frontside of the first source/drain region and a local interconnect extending horizontally from the frontside contact to at least a portion of an area of an interlayer dielectric layer disposed over a frontside of the second source/drain region.

10. The semiconductor structure of claim 1, further comprising one or more gate stacks and gate spacers surrounding the one or more gate stacks, wherein the second source/drain region comprises epitaxial layers which extend toward the one or more gate stacks underneath the gate spacers.

11. A nanosheet transistor structure, comprising:
an n-type source/drain region having diamond-shaped sidewalls; and
a p-type source/drain region having trench-confined sidewalls;
wherein at least one of the n-type source/drain region and the p-type source/drain region is disposed over a placeholder layer.

12. The nanosheet transistor structure of claim 11, wherein the p-type source/drain region and the placeholder layer each comprise silicon germanium (SiGe), and wherein a first germanium (Ge) percentage of the p-type source/drain region is greater than a second Ge percentage of the placeholder layer.

13. The nanosheet transistor structure of claim 11, wherein the n-type source/drain region is disposed over the placeholder layer, and further comprising a backside contact to the p-type source/drain region.

14. The nanosheet transistor structure of claim 13, further comprising a dielectric liner disposed over shallow trench isolation regions surrounding a portion of sidewalls of the backside contact.

15. The nanosheet transistor structure of claim 11, further comprising one or more gate stacks and gate spacers surrounding the one or more gate stacks, wherein the p-type source/drain region comprises epitaxial layers which extend toward the one or more gate stacks underneath the gate spacers.

16. An integrated circuit comprising:
a nanosheet transistor structure comprising:
an n-type source/drain region having diamond-shaped sidewalls; and
a p-type source/drain region having trench-confined sidewalls;
wherein at least one of the n-type source/drain region and the p-type source/drain region is disposed over a placeholder layer.

17. The integrated circuit of claim 16, wherein the p-type source/drain region and the placeholder layer each comprise silicon germanium (SiGe), and wherein a first germanium (Ge) percentage of the p-type source/drain region is greater than a second Ge percentage of the placeholder layer.

18. The integrated circuit of claim 16, wherein the n-type source/drain region is disposed over the placeholder layer, and further comprising a backside contact to the p-type source/drain region.

19. The integrated circuit of claim 18, further comprising a dielectric liner disposed over shallow trench isolation regions surrounding a portion of sidewalls of the backside contact.

20. The integrated circuit of claim 16, wherein the nanosheet transistor structure further comprises one or more gate stacks and gate spacers surrounding the one or more gate stacks, wherein the p-type source/drain region comprises epitaxial layers which extend toward the one or more gate stacks underneath the gate spacers.
